(19) United States
(12) Patent Application Publication
(10) Pub. No.: US 2026/0101760 A1
(43) Pub. Date: Apr. 9, 2026

(54) SEMICONDUCTOR DEVICE

(71) Applicant: Samsung Electronics Co., Ltd., Suwon-si (KR)

(72) Inventors: Seungmin LEE, Suwon-si (KR); Seokwoo HONG, Suwon-si (KR); Minkyu KANG, Suwon-si (KR); Jaesun YUN, Suwon-si (KR); Joon-Sung LIM, Suwon-si (KR); Jieun HA, Suwon-si (KR)

(73) Assignee: Samsung Electronics Co., Ltd., Suwon-si (KR)

(21) Appl. No.: 19/256,997

(22) Filed: Jul. 1, 2025

(30) Foreign Application Priority Data
Oct. 8, 2024 (KR) 10-2024-0136394

(51) Int. Cl. H01L 23/60; H01L 23/00; H01L 23/498; H01L 23/58; H01L 25/065; H10B 12/00; H10B 80/00

(52) U.S. Cl. CPC H10W 42/60; H10B 12/488; H10B 12/50; H10B 80/00; H10W 42/00; H10W 70/69; H10W 90/00; H10W 72/0198; H10W 80/312; H10W 80/327; H10W 90/792

(57) ABSTRACT

A semiconductor device may include a substrate having a chip region and a scribe lane region, the chip region including a plurality of chips arranged in a first direction and in a second direction, the second direction crossing the first direction, the scribe lane region surrounding the chip region, a peripheral circuit structure on the substrate, the peripheral circuit structure including a transistor with a gate and an active region, a cell structure on the peripheral circuit structure, a protective layer on at least a portion of the cell structure, and a discharge structure penetrating through the cell structure in a third direction, the third direction crossing each of the first direction and the second direction, the discharge structure electrically connected to the substrate. An upper surface of the discharge structure is exposed to an outside of the cell structure.

### CROSS-REFERENCE TO RELATED APPLICATION

This application claims priority to Korean Patent Application No. 10-2024-0136394, filed in the Korean Intellectual Property Office on Oct. 8, 2024, the entire contents of which are hereby incorporated by reference.

### BACKGROUND

### Field

The present disclosure relates to semiconductor devices.

### Description of Related Art

A semiconductor device is a core component used in an electronic device to control or amplify an electrical signal, and various types of semiconductor devices may be manufactured. For example, memory devices may be used primarily to store and retrieve data, while non-memory devices may be used to control or amplify electrical signals. The semiconductor device is a core element of an electronic device and plays an important role in various fields including computers, communication equipment, consumer electronics, etc.

During manufacturing or use of the semiconductor device, the semiconductor device may be subjected to an electrical shock due to unexpected electrostatic discharges. Because the electrostatic discharges can degrade the mechanical and/or electrical characteristics of the semiconductor device, it is desired to protect the semiconductor device from the electrostatic discharges.

### SUMMARY

In order to solve one or more problems (e.g., the problems described above and/or other problems not explicitly described herein), some example embodiments of the present disclosure provide semiconductor devices capable of ensuring mechanical and/or electrical characteristics.

In order to solve one or more problems (e.g., the problems described above and/or other problems not explicitly described herein), the present disclosure provides semiconductor devices capable of protecting a chip region from electrostatic discharges.

In order to solve one or more problems (e.g., the problems described above and/or other problems not explicitly described herein), some example embodiments of the present disclosure provide a semiconductor device including a discharge structure capable of protecting a chip region from electrostatic discharges.

According to an example embodiment of the present disclosure, a semiconductor device may include a substrate including a chip region and a scribe lane region, the chip region including a plurality of chips arranged in a first direction and in a second direction, the second direction intersecting the first direction, the scribe lane region surrounding the chip region, a peripheral circuit structure on the substrate, the peripheral circuit structure including a transistor with a gate and an active region, a cell structure on the peripheral circuit structure, a protective layer on at least a portion of the cell structure, and a discharge structure penetrating the cell structure in a third direction, the third direction intersecting each of the first direction and the second direction, the discharge structure electrically connected to the substrate, wherein an upper surface of the discharge structure is exposed to an outside of the cell structure.

According to an example embodiment of the present disclosure, a semiconductor device may include a substrate including a chip region and a scribe lane region, the chip region including a plurality of chips arranged in a first direction and in a second direction, the second direction intersecting the first direction, the scribe lane region surrounding the chip region, a peripheral circuit structure on the substrate, the peripheral circuit structure including a transistor with a gate and an active region, a cell structure on the peripheral circuit structure, a protective layer on at least a portion of the cell structure, and a first discharge structure penetrating the cell structure in a third direction, the third direction intersecting each of the first direction and the second direction, the first discharge structure electrically connected to the substrate, wherein an upper surface of the first discharge structure is exposed to an outside of the cell structure.

According to an example embodiment of the present disclosure, a semiconductor device may include a substrate including a chip region and a scribe lane region, the chip region including a plurality of chips arranged in a first direction and in a second direction, the second direction intersecting the first direction, the scribe lane region surrounding the chip region, a peripheral circuit structure on the substrate, the peripheral circuit structure including a transistor with a gate and an active region, a cell structure on the peripheral circuit structure, a protective layer on an upper surface of the cell structure and covering at least a portion of the cell structure, and a discharge structure extending through the cell structure in a third direction, the third direction crossing each of the first direction and the second direction, an upper surface of the discharge structure not overlapping the protective layer in the third direction and exposed to an outside of the cell structure, and the peripheral circuit structure further includes a peripheral conductive line, the peripheral conductive line electrically connecting a lower surface of the discharge structure to the active region.

According to an example embodiment of the present disclosure, a method for manufacturing a semiconductor device may include providing a cell structure on a substrate, the substrate including a chip region and a scribe lane region surrounding the chip region, forming a block structure through the cell structure at a boundary between the chip region and the scribe lane region, forming a discharge structure through the cell structure, the discharge structure being spaced apart from the block structure in a horizontal direction, forming a protective layer on the cell structure, and etching, using a mask pattern, the protective layer and a portion of the cell structure underneath to form an aperture exposing the discharge structure thereunder.

The forming of the discharge structure may form the discharge structure in the subscribe lane region.

According to some example embodiments of the present disclosure, the semiconductor device may ensure mechanical and/or electrical characteristics.

According to some example embodiments of the present disclosure, the semiconductor device may protect the chip region from electrostatic discharges.

According to some example embodiments of the present disclosure, the semiconductor device may include a discharge structure capable of protecting the chip region from electrostatic discharges, thereby reducing or preventing electrostatic shock that may occur during a manufacturing process or use of the semiconductor device.

### BRIEF DESCRIPTION OF THE DRAWINGS

The above and other objects, features and advantages of the present disclosure will become more apparent to those of ordinary skill in the art by describing in detail some example embodiments thereof with reference to the accompanying drawings, in which:

FIG. 1 is a plan view illustrating a semiconductor wafer according to an example embodiment;

FIG. 2 is an enlarged view of the region A of FIG. 1;

FIG. 3 is a cross-sectional view schematically illustrating a cross-section taken along line B-B′ of FIG. 2;

FIG. 4 is a cross-sectional view illustrating a discharge structure according to an example embodiment;

FIG. 5 is a diagram explaining the principles of protecting a semiconductor device from electrostatic discharges;

FIG. 6 is a cross-sectional view illustrating a discharge structure according to an example embodiment;

FIG. 7 is an enlarged view of the region A of FIG. 1;

FIGS. 8 and 9 are cross-sectional views schematically illustrating a semiconductor device according to some example embodiments;

FIG. 10 is a plan view illustrating the semiconductor device of FIG. 9;

FIGS. 11 to 12 are diagrams illustrating intermediate stages of manufacturing a semiconductor device according to an example embodiment;

FIGS. 13 to 15 are cross-sectional views illustrating a semiconductor device including a discharge structure according to some example embodiments; and

FIGS. 16 and 17 are diagrams provided to explain a discharge structure according to an example embodiment.

### DETAILED DESCRIPTION

A semiconductor device according to some examples of the present disclosure will be described in detail with reference to the drawings.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

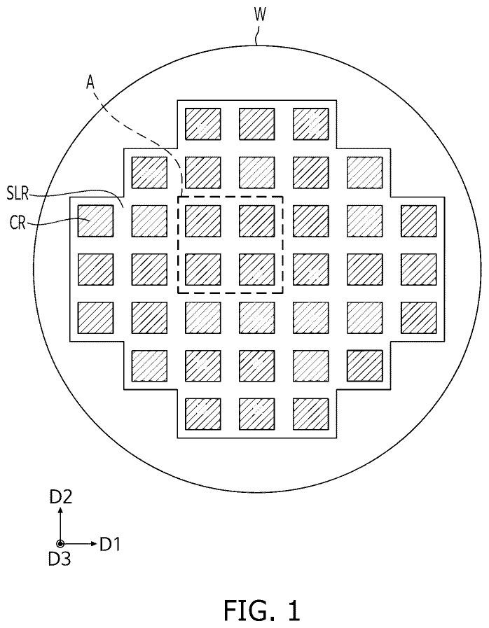

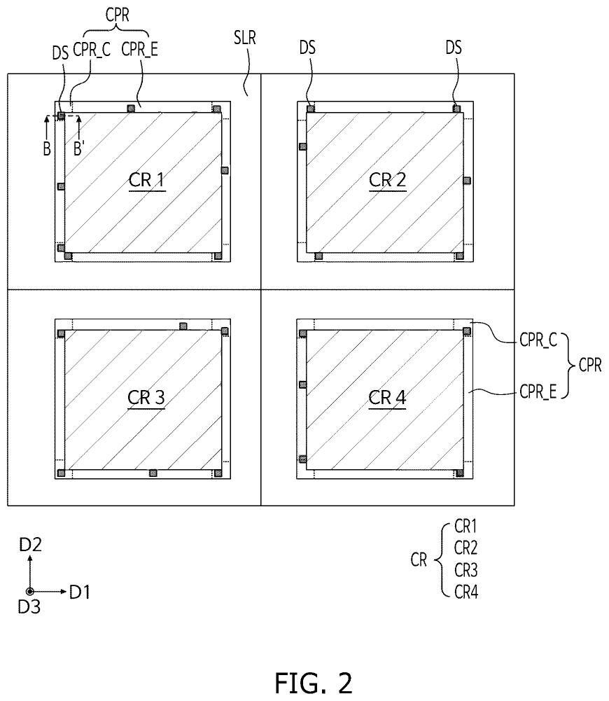

FIG. 1 is a plan view illustrating a semiconductor wafer according to an example embodiment. FIG. 2 is an enlarged view of the region A of FIG. 1.

Referring to FIGS. 1 and 2, a semiconductor wafer W may be provided. For example, the semiconductor wafer W may include a silicon wafer. The semiconductor wafer W may include a plurality of chip regions CR arranged along a first direction D1 and a second direction D2. The first direction D1 and the second direction D2 may cross each other and may be orthogonal, for example.

The chip regions CR may be surrounded by a scribe lane region SLR. The chip regions CR may be spaced apart from each other by a scribe lane region SLR in a shape of a lattice pattern extending along the first and second directions D1 and D2.

In some example embodiments, the semiconductor device may include a chip region CR and a scribe lane region SLR surrounding the chip region CR. The chip region CR may be a high-density region having a relatively high pattern density, and the scribe lane region SLR may be a low-density region having a relatively low pattern density or having no pattern. The chip region CR may include a cell array region of a semiconductor memory device, a peripheral circuit region including circuits configured to be electrically connectable to cell arrays included in the cell array region, and a core region. In some example embodiments, the chip region CR may include a memory device. Meanwhile, the chip region CR may include a non-memory device, but example embodiments are not limited thereto.

In some example embodiments, the chip region CR may include at least one non-volatile memory device. For example, the at least one non-volatile memory device may include a NAND flash memory, a vertical NAND flash memory (VNAND), a NOR flash memory (NOR flash memory), a resistive random access memory (RRAM), a phase-change memory (PRAM), a magnetoresistive random access memory (MRAM), a ferroelectric random access memory (FRAM), a spin transfer torque random access memory (STT-RAM), or a combination thereof.

The memory device may be implemented in a three-dimensional array structure. For example, the chip region CR may include a cell array region and a peripheral circuit structure included in the semiconductor device. In some example embodiments, the memory device may further include a volatile memory device such as a dynamic random access memory (DRAM).

Referring to FIG. 2, first to fourth chip regions CR1 to CR4 may be disposed in a grid pattern along the first direction D1 and the second direction D2 intersecting the first direction D1. Each of the first to fourth chip regions CR1 to CR4 may be surrounded by the scribe lane region SLR.

The scribe lane region SLR may include a chip peripheral region CPR formed around the chip region CR. The chip peripheral region CPR may be a part provided to block or prevent mechanical or electrical damages to the chip region CR. The scribe lane region SLR excluding the chip peripheral region CPR may be a region to be cut by a die singulation process or a sawing process.

The chip peripheral region CPR may be a partial region of the scribe lane region SLR that remains around the chip region CR without being removed in the process of performing the die singulation process or sawing process on the chip region CR.

The chip peripheral region CPR may include an edge region CPR_E corresponding to an edge of the chip region CR and a corner region CPR_C corresponding to a corner of the chip region CR. The corner region CPR_C may be the remaining part of the chip peripheral region CPR except for the edge region CPR_E. The edge region CPR_E may be positioned between adjacent corner regions CPR_C. The corner region CPR_C may connect the adjacent edge regions CPR_E.

A discharge structure DS may be disposed in the scribe lane region SLR. The discharge structure DS may be disposed at a position adjacent to a periphery of the chip region CR. For example, the discharge structure DS may be disposed in the chip peripheral region CPR. The discharge structure DS may be disposed at a location where electric charge is likely to accumulate. The discharge structure DS may be disposed at a position adjacent to a corner of each of the first to fourth chip regions CR1 to CR4. The discharge structure DS may also be disposed at a position adjacent to an edge of each of the first to fourth chip regions CR1 to CR4. That is, the discharge structure DS may be disposed in at least one of the corner region CPR_C or the edge region CPR_E. In some example embodiments, a part of the discharge structure DS may be positioned in the corner region CPR_C, and the remaining part of the discharge structure DS may be positioned in the edge region CPR_E. The discharge structure DS may span the corner region CPR_C and the edge region CPR_E.

The discharge structure DS and configurations around the same will be described in detail.

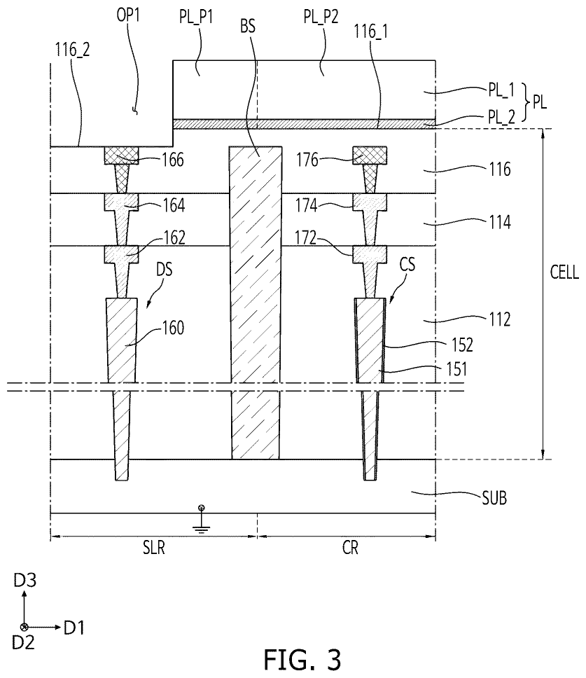

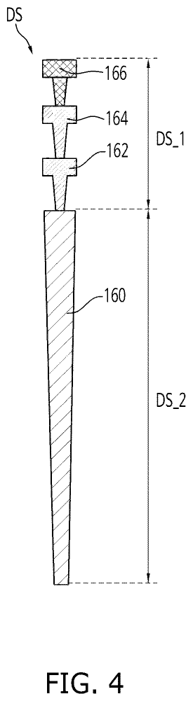

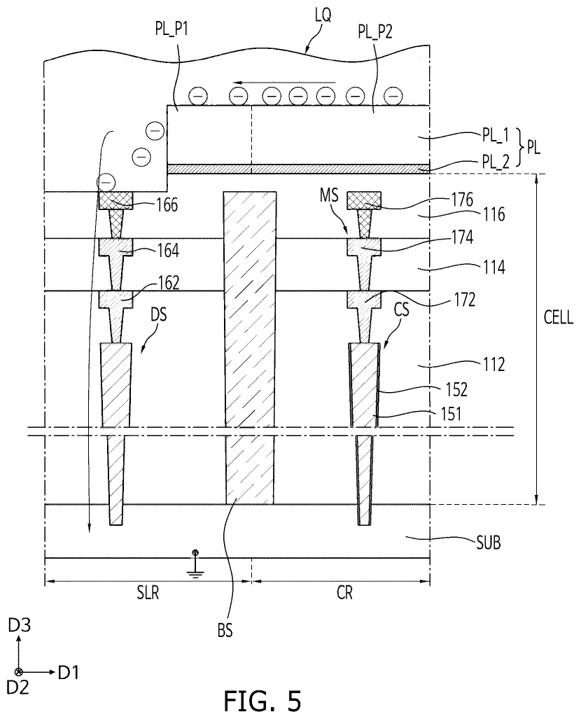

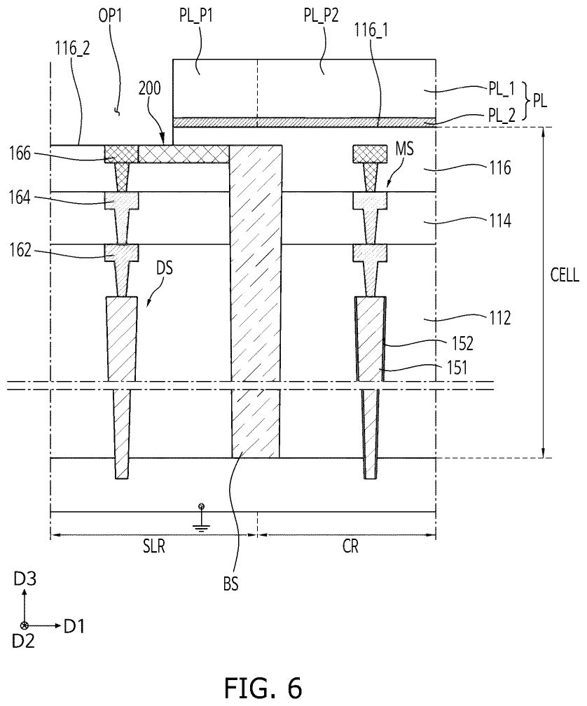

FIG. 3 is a cross-sectional view schematically illustrating a cross-section taken along line B-B′ of FIG. 2. FIG. 4 is a cross-sectional view illustrating a discharge structure according to an example embodiment. FIG. 5 is a diagram explaining the principles of protecting a semiconductor device from electrostatic discharges. FIG. 6 is a cross-sectional view illustrating a discharge structure according to an example embodiment.

Referring to FIGS. 3 and 4, a semiconductor device chip region CR and a scribe lane region SLR according to an example embodiment may be included. The chip region CR and the scribe lane region SLR may be partitioned by a block structure BS. However, this is merely illustrative, and they may be partitioned by other structures or may be determined according to the design of the semiconductor device.

The semiconductor device may include a substrate SUB, a cell structure CELL, the discharge structure DS, a block structure BS, a contact structure CS, a protective layer PL, and a first opening OP1. Throughout the present disclosure, each of various openings described in the present disclosure may be interchangeably referred to as an aperture.

The substrate SUB may be a semiconductor substrate. For example, the substrate SUB may include silicon (Si), germanium (Ge), or silicon germanium (SiGe). The substrate SUB may include a semiconductor doped with dopants having a conductivity type (e.g., a p-type) and/or an intrinsic semiconductor undoped with impurities. A ground voltage may be applied to the substrate SUB. For example, the substrate SUB may have a ground structure including a ground pad or a ground wiring, etc.

The cell structure CELL may be provided on the substrate SUB. The cell structure CELL may be disposed in each of the chip region CR and the scribe lane region SLR. The cell structure CELL may include a first interlayer insulating film 112, a second interlayer insulating film 114, and a third interlayer insulating film 116. In some example embodiments, an etch stop layer (e.g., silicon nitride (SiN)) may be disposed between the first interlayer insulating film 112, the second interlayer insulating film 114, and the third interlayer insulating film 116.

The discharge structure DS, the block structure BS, and the contact structure CS may be provided in the cell structure CELL.

The discharge structure DS may be formed through the cell structure CELL in a third direction D3. The discharge structure DS may penetrate the cell structure CELL in a third direction D3. The discharge structure DS may be formed through the first interlayer insulating film 112, the second interlayer insulating film 114, and the third interlayer insulating film 116 in the third direction D3. The third direction D3 may intersect (e.g., perpendicularly) each of the first direction D1 and the second direction D2. The third direction D3 may be a vertical direction. An upper surface of the discharge structure DS may be exposed to the outside of the cell structure CELL. The first opening OP1 may be formed above the discharge structure DS. The upper surface of the discharge structure DS may be exposed to the outside of the cell structure through the first opening OP1.

The discharge structure DS may be electrically connected to the substrate SUB. The discharge structure DS may be in physical contact with and electrically connected to the substrate SUB. For example, a lower surface of the discharge structure DS may be in contact with the substrate SUB. In some example embodiments, the lower surface of the discharge structure DS may be positioned within the substrate SUB. The discharge structure DS may be electrically connected to the substrate SUB by a different configuration. For example, a conductive member may be additionally provided between the discharge structure DS and the substrate SUB.

The discharge structure DS may include a first structure DS_1 and a second structure DS_2.

The first structure DS_1 may be disposed above the second structure DS_2. An upper surface of the first structure DS_1 may be exposed to the outside of the cell structure CELL. The first structure DS_1 may be a multi-layered wiring structure. The first structure DS_1 may include a first upper wiring layer 162, a second upper wiring layer 164, and a third upper wiring layer 166. The first upper wiring layer 162, the second upper wiring layer 164, and the third upper wiring layer 166 may be disposed within the first interlayer insulating film 112, the second interlayer insulating film 114, and the third interlayer insulating film 116, respectively.

Each of the first upper wiring layer 162, the second upper wiring layer 164, and the third upper wiring layer 166 may include tungsten, titanium, tantalum, copper, aluminum, titanium nitride, tantalum nitride, tungsten nitride, or a combination thereof. However, example embodiments are not limited thereto, and the first structure DS_1 may be provided as a single layer (e.g., an integral body).

The second structure DS_2 may be connected to a lower surface of the first structure DS_1. The second structure DS_2 may extend in the third direction D3. That is, the second structure DS_2 may extend in the vertical direction. A lower end of the second structure DS_2 may be a terminal for electrical connection to the substrate SUB. The second structure DS_2 may be in physical contact with the substrate SUB or may be electrically connected to the substrate SUB by a separate configuration. For example, the second structure DS_2 may be a through via 160.

The first structure DS_1 and the second structure DS_2 may have conductivity. The first structure DS_1 and the second structure DS_2 may be formed by different processes. The first structure DS_1 may include metal. For example, the first structure DS_1 may include copper, tungsten, aluminum, etc. The second structure DS_2 may include various materials. For example, the second structure DS_2 may include copper, tungsten, aluminum, polysilicon, etc. In some example embodiments, the first structure DS_1 and the second structure DS_2 may include the same material. The first structure DS_1 and the second structure DS_2 may be integrally formed. For example, the first structure DS_1 and the second structure DS_2 may be formed by a single process.

Referring to FIG. 3, the block structure BS may be disposed on the substrate SUB. The block structure BS may be disposed at a boundary between the chip region CR and the scribe lane region SLR. The block structure BS may be disposed at a position overlapping with the boundary between the chip region CR and the scribe lane region SLR in the third direction D3.

The block structure BS may extend in the third direction D3. The block structure BS may extend in a vertical direction. The block structure BS may be formed through a portion of the cell structure CELL in the third direction D3. The block structure BS may be formed through the first interlayer insulating film 112, the second interlayer insulating film 114, and the third interlayer insulating film 116 in the third direction D3. The block structure BS may partition the chip region CR and the scribe lane region SLR. The block structure BS may physically partition the chip region CR and the scribe lane region SLR.

The block structure BS may reduce or prevent mechanical damage that may occur in the chip region CR. For example, the block structure BS may be a guard ring. The mechanical damage may include stress, etc. that may occur during the die singulation process or the sawing process. In addition, the block structure BS may reduce or prevent damage caused by heat generation, subsequent temperature changes, etc., which may occur as the semiconductor chip is used. The block structure BS may include a metal material. For example, the block structure BS may include tungsten W.

An upper surface of the block structure BS may be positioned at the same level as the upper surface of the discharge structure DS. A lower surface of the block structure BS may be in contact with the substrate SUB. In some example embodiments, the block structure BS may have the same structure as the discharge structure DS. That is, the block structure BS may have a structure corresponding to the first and second structures DS_1 and DS_2 of the discharge structure DS. The contact structure CS may be disposed in the cell region CR. The contact structure CS may extend in the third direction D3. The contact structure CS may extend in a vertical direction. The contact structure CS may be formed through a portion of the cell structure CELL in the third direction D3. The contact structure CS may be formed through the first interlayer insulating film 112, the second interlayer insulating film 114, and the third interlayer insulating film 116 in the third direction D3. A plurality of contact structures CS may be provided.

The contact structure CS may include a contact plug 151 extending in the third direction D3. A sidewall of the contact plug 151 may be surrounded by a contact insulating film 152. The contact structure CS may include a wiring structure disposed on an upper portion thereof. A lower end of the contact structure CS may be connected to the substrate SUB.

The upper surface of the contact structure CS may be positioned at the same vertical level as each of the upper surface of the discharge structure DS and the upper surface of the block structure BS. That is, the upper surface of the wiring structure of the contact structure CS and the upper surface of the first structure DS_1 of the discharge structure DS may be positioned at the same vertical level.

The protective layer PL may be disposed on at least a portion of the cell structure CELL. The protective layer PL may be disposed in both the chip region CR and the scribe lane region SLR. In some example embodiments, the protective layer PL may not be disposed on the scribe lane region SLR.

The protective layer PL may include a first protective layer PL_1 and a second protective layer PL_2. The second protective layer PL_2 and the first protective layer PL_1 may be sequentially stacked on the cell structure CELL. For example, the second protective layer PL_2 may be stacked on the third interlayer insulating film 116, and the first protective layer PL_1 may be stacked on the second protective layer PL_2. The third interlayer insulating film 116 may include an insulating material having an etching selectivity with respect to the second protective layer PL_2. The first protective layer PL_1 may include silicon nitride (SiN), and the second protective layer PL_2 may include a photosensitive insulating film. For example, the second protective layer PL_2 may include a polyimide-based material such as photosensitive polyimide (PSPI).

The protective layer PL may include a first portion PL_P1 positioned on the scribe lane region SLR and a second portion PL_P2 positioned on the chip region CR. That is, the boundary between the first portion PL_P1 and the second portion PL_P2 of the protective layer PL may correspond to the boundary between the chip region CR and the scribe lane region SLR. The boundary between the first portion PL_P1 and the second portion PL_P2 may overlap the block structure BS in the third direction D3.

The protective layer PL may be disposed on the third interlayer insulating film 116. The third interlayer insulating film 116 may be disposed at a lower vertical level than the protective layer PL. The third interlayer insulating film 116 may be disposed on a lower surface of the protective layer PL. The third interlayer insulating film 116 may include a first surface 116_1 in contact with the lower surface of the protective layer PL, and a second surface 116_2 uncovered by the protective layer PL.

The upper surface of the discharge structure DS may be exposed to the outside of the cell structure CELL through the first opening OP1. The first opening OP1 may be formed by removing portions of the protective layer PL and the third interlayer insulating film 116 by etching. A portion of an upper surface of the third interlayer insulating film 116 remaining after removal by etching may be referred to as the second surface 116_2.

The upper surface of the discharge structure DS may be exposed through the second surface 116_2. The discharge structure DS may not be covered by the protective layer PL. The discharge structure DS may not overlap the second portion PL_P2 of the protective layer PL in the third direction D3. The upper surface of the discharge structure DS may not overlap the second portion PL_P2 of the protective layer PL in the third direction D3 in the scribe lane region SLR.

The second surface 116_2 may be positioned at a lower vertical level than the first surface 116_1. A step difference may be formed between the second surface 116_2 and the first surface 116_1. The second surface 116_2 and the upper surface of the discharge structure DS may be positioned at the same vertical level. Because the upper surface of the discharge structure DS and the upper surface of the contact structure CS are positioned at the same vertical level, the upper surface of the contact structure CS may be spaced apart from the lower surface of the protective layer PL (e.g., from the first surface 116_1) in the third direction D3.

Referring to FIG. 5, electrostatic electricity may be formed in the semiconductor device due to tribocharging effect, etc. Electrons may be generated on the protective layer PL. The wafer may be formed into semiconductor chips by a die singulation process and formed into a semiconductor package by a packaging process. The semiconductor package may undergo a cleaning process using a processing liquid LQ. For example, the processing liquid LQ may be deionized water DIW. However, this is only an example, and the electrostatic electricity may be formed by other processes or during the use of the semiconductor device.

As a non-limiting example, friction may occur due to a difference between speed of the first protective layer PL_1 and speed of the deionized water. Electrons may be generated by the friction between the first protective layer PL_1 and the deionized water and accumulated on the first protective layer PL_1. For example, the first protective layer PL_1 may be charged with negative charge, and the processing liquid LQ may be charged with positive charge. As described above, the generated electrons may be accumulated on the first protective layer PL_1, creating a potential difference, and may move to the substrate SUB through an internal wiring or a conductive structure of the semiconductor device, during which defects may occur. It is desired to reduce or prevent the generated electrons from flowing into the structure inside the chip region CR.

The discharge structure DS may release the electrons accumulated by friction, etc. The discharge structure DS may be disposed in the scribe lane region SLR. Because the upper surface of the discharge structure DS is exposed to the outside of the cell structure CELL, the electrons may flow into the discharge structure DS through the exposed upper surface of the discharge structure DS.

The discharge structure DS may be disposed at a position adjacent to the protective layer PL. The electrons accumulated on the protective layer PL may flow into the discharge structure DS through the upper surface of the discharge structure DS, and move along the discharge structure DS and discharged through the grounded substrate SUB. In addition, because current is induced to flow through the discharge structure DS, the current may be reduced or prevented from flowing into the elements formed in the cell region CR.

Referring to FIG. 6, a semiconductor device according to some example embodiments may include the discharge structure DS, the block structure BS, and a connection member 200. The discharge structure DS and the block structure BS may be electrically connected to each other through the connection member 200. For example, the connection member 200 may connect a third upper wiring layer 166 of the discharge structure DS to an upper end of the block structure BS. However, a connection structure of the connection member 200 is not limited to the above. The connection member 200 may include a conductive material. The connection member 200 may include the same material as the discharge structure DS or the block structure BS.

The electrons flowing into the discharge structure DS through the upper surface of the discharge structure DS may flow along the discharge structure DS or along the connection member 200 and the block structure BS. With the addition of a path for current flow, both current density and resistance may decrease.

A different aspect from those of FIGS. 2 to 6 will be described. Elements that are similar to those already described above may be given the same reference numerals, and detailed description thereof may be omitted.

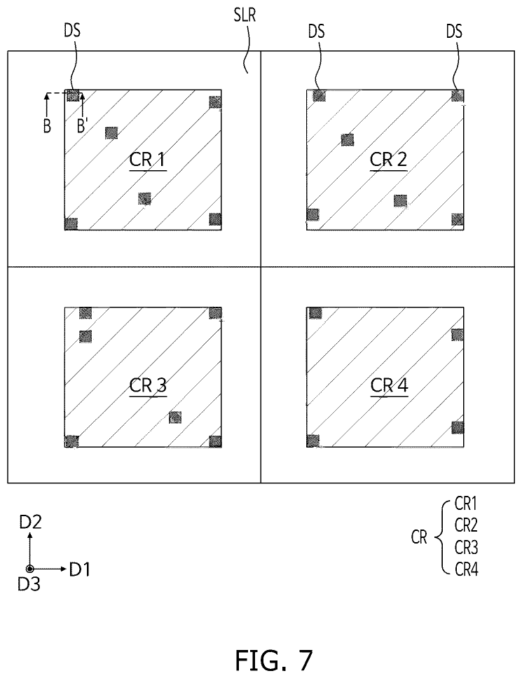

FIG. 7 is an enlarged view of the region A of FIG. 1.

Referring to FIG. 7, the first to fourth chip regions CR1 to CR4 may be disposed in a lattice shape along the first direction D1 and the second direction D2 intersecting the first direction D1. Each of the first to fourth chip regions CR1 to CR4 may be surrounded by the scribe lane region SLR.

The discharge structure DS may be disposed in each of the first to fourth chip regions CR1 to CR4. The discharge structure DS may be disposed in the chip region CR. The discharge structure DS may be disposed at a position adjacent to the edge of the chip region CR. The discharge structure DS may be disposed at a location where electric charge is likely to accumulate. For example, the discharge structure DS may be disposed at a corner of the chip region CR. However, example embodiments are not limited to the above, and the discharge structure DS may also be disposed at a position adjacent to the edge of the chip region CR.

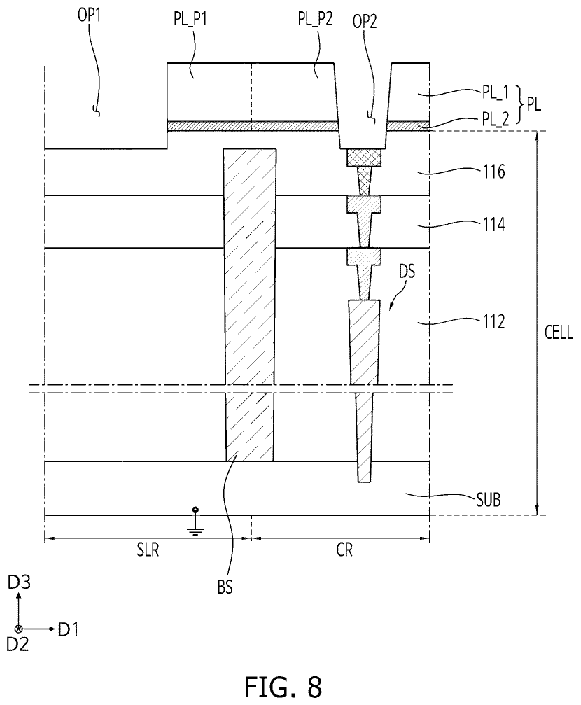

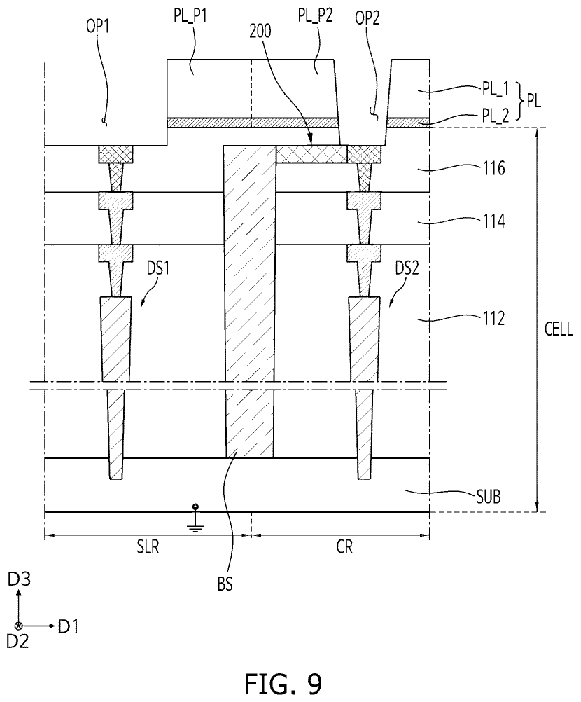

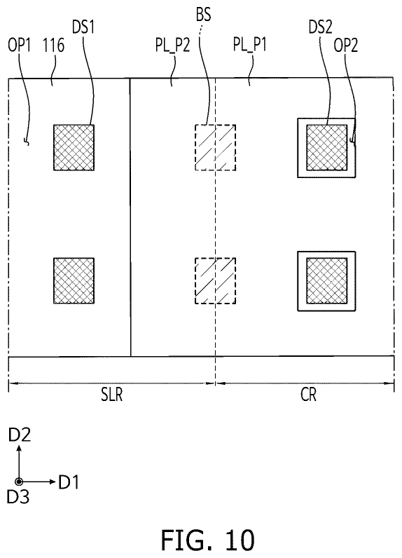

FIGS. 8 and 9 are cross-sectional views schematically illustrating a semiconductor device according to some example embodiments. FIG. 10 is a plan view illustrating the semiconductor device of FIG. 9.

Referring to FIG. 8, the semiconductor device according to an example embodiment may include a second opening OP2 formed in the cell region CR. The second opening OP2 may be formed on an upper portion of the cell structure CELL. The second opening OP2 may be formed through at least a portion of the protective layer PL and the cell structure CELL in the third direction D3. The second opening OP2 may be formed by patterning a portion of the protective layer PL and a portion of the interlayer insulating film 116.

The discharge structure DS may be disposed at a position overlapping the second opening OP2 in the third direction D3. The upper surface of the discharge structure DS may overlap the second opening OP2 in the third direction D3. The upper surface of the discharge structure DS may be exposed to the outside of the cell structure CELL through the second opening OP2.

Electrons generated around the protective layer PL may flow into the discharge structure DS through the upper surface of the discharge structure DS. The electrons flowing through the discharge structure DS may flow to the grounded substrate SUB.

Referring to FIGS. 9 and 10, the semiconductor device may include a first discharge structure DS1, a second discharge structure DS2, and the second opening OP2 formed in the cell region CR.

The first discharge structure DS1 may be disposed in the scribe lane region SLR. The first discharge structure DS1 may be formed through the cell structure CELL in the third direction D3. An upper surface of the first discharge structure DS1 may be exposed to the outside of the cell structure CELL. The upper surface of the first discharge structure DS1 may not overlap the protective layer PL in the third direction D3.

The second discharge structure DS2 may be disposed in the chip region CR. The second discharge structure DS2 may be formed through the cell structure CELL in the third direction D3. The second discharge structure DS2 may overlap the second opening OP2 in the third direction D3. An upper surface of the second discharge structure DS2 may be exposed to the outside of the cell structure CELL through the second opening OP2.

A plurality of first discharge structures DS1 and a plurality of second discharge structures DS2 may be provided. For example, the first discharge structures DS1 may be disposed to be spaced apart from each other and the second discharge structures DS2 may be disposed to be spaced apart from each other by a desired (or alternatively, predetermined) distance in the second direction D2 (e.g., horizontal direction). The plurality of first discharge structures DS1 may be connected to each other or only some of them may be connected to each other. The plurality of second discharge structures DS2 may be connected to each other or only some of them may be connected to each other.

A plurality of block structures BS may be provided. The block structures BS may be spaced apart from each other by a desired (or alternatively, predetermined) distance in the second direction D2. However, this is only an example, and the plurality of block structures BS may have various structures such as being connected to each other.

The upper surface of the second discharge structure DS2 may be open in the third direction D3. No separate wiring may be connected to the upper surface of the second discharge structure DS2. That is, the entire upper surface of the second discharge structure DS2 may be exposed in the third direction D3. In other words, there may be no configuration in the second opening OP2 that overlaps the protective layer PL in the first direction D1 or the second direction D2.

In some example embodiments, the second opening OP2 may expose only a part of the upper surface of the second discharge structure DS2. That is, the second opening OP2 exposes only a part of the upper surface of the second discharge structure DS2, and the remaining part may be covered by the protective layer PL or the third interlayer insulating film 116.

The second opening OP2 may be formed by patterning the protective layer PL and the third interlayer insulating film 116. Although the cross-section of the opening OP is illustrated as rectangular, example embodiments are not limited thereto.

The second discharge structure DS2 may be electrically connected to the block structure BS. The second discharge structure DS2 and the block structure BS may be electrically connected to each other through the connection member 200. For example, the connection member 200 may connect the third upper wiring layer of the second discharge structure DS2 to the upper end of the block structure BS. However, a connection structure of the connection member 200 is not limited to the above. In some example embodiments, each of the first discharge structure DS1 and the second discharge structure DS2 may be electrically connected to the block structure BS. In some example embodiments, some of the first discharge structure DS1 and the second discharge structure DS2 may be electrically connected to the block structure BS.

Through the second opening OP2, the electrons may flow into the second discharge structure DS2 through the upper surface of the second discharge structure DS2. The electrons flow into the second discharge structure DS2 through the upper surface of the second discharge structure DS2 may flow along the second discharge structure DS2 or may flow along the block structure BS through the connection member 200 to the grounded substrate SUB. With the addition of a path for current flow, both current density and resistance may decrease.

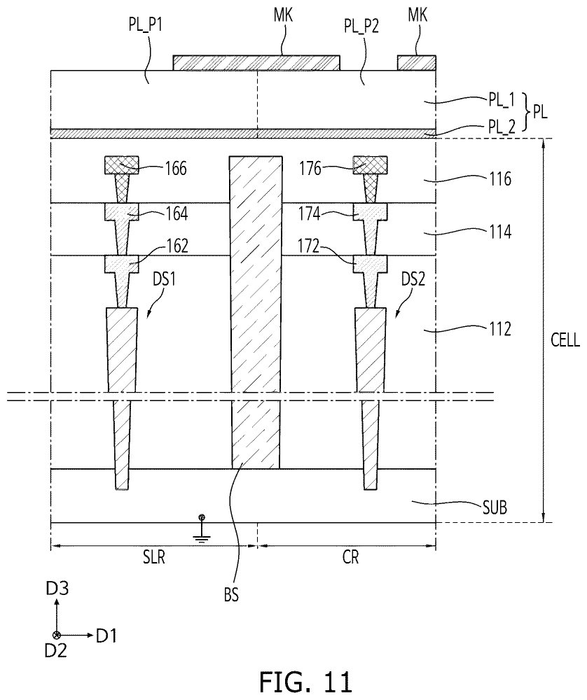

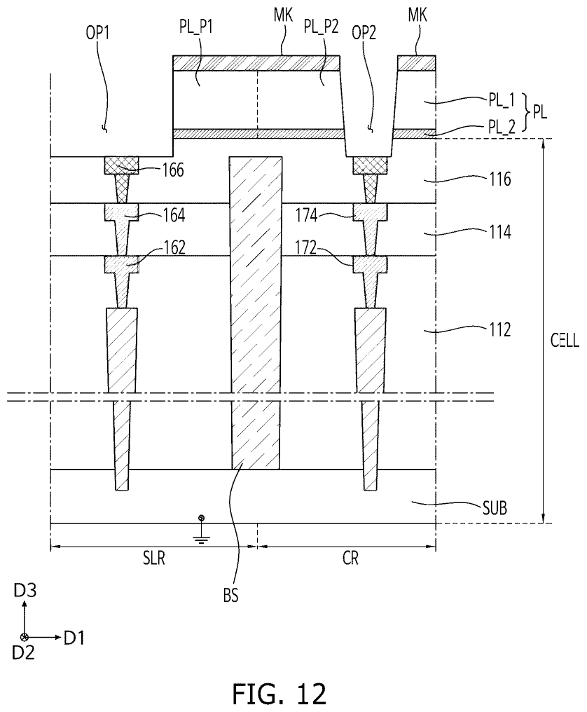

FIGS. 11 to 12 are diagrams illustrating intermediate stages of manufacturing a semiconductor device according to an example embodiment.

With reference to FIGS. 11 and 12, a method for manufacturing a semiconductor device including the first discharge structure DS1 and the second discharge structure DS2 will be described.

First, referring to FIG. 11, the semiconductor device may include the first discharge structure DS1 and the second discharge structure DS2 formed through the cell structure CELL in the third direction D3. The protective layer PL may be disposed on an upper surface of the cell structure CELL. The second protective layer PL_2 and the first protective layer PL_1 may be sequentially stacked on the cell structure CELL. The protective layer PL may be disposed in both the cell region CR and the scribe lane region SLR. The protective layer PL may overlap each of the first discharge structure DS1 and the second discharge structure DS2 in the third direction D3.

Referring to FIGS. 11 and 12, a portion of the protective layer PL and a portion of the cell structure CELL may be etched so that the upper surface of the first discharge structure DS1 and the upper surface of the second discharge structure DS2 are exposed to the outside of the cell structure CELL. The etching may be performed at positions corresponding to each of the upper surface of the first discharge structure DS1 and the upper surface of the second discharge structure DS2 in the third direction D3.

A mask pattern MK may be disposed on the protective layer PL. The mask pattern MK may be an etching mask for exposing the first and second discharge structures DS1 and DS2. The mask pattern MK may not be disposed at positions corresponding to the upper surface of the first discharge structure DS1 and the upper surface of the second discharge structure DS2 in the third direction D3. In other words, the mask pattern MK may be disposed at positions that do not correspond to the upper surface of the first discharge structure DS1 and the upper surface of the second discharge structure DS2 in the third direction D3.

An area where no mask pattern MK is present may be removed by etching. For example, a portion of the protective layer PL and a portion the third interlayer insulating film 116 may be removed. As the upper surface of the first discharge structure DS1 and the upper surface of the second discharge structure DS2 are positioned at the same level, the etching depth may be the same.

By the etching process, the first opening OP1 may be formed in the scribe lane region SLR, and the second opening OP2 may be formed in the chip region CR. The upper surface of the first discharge structure DS1 may be exposed to the outside of the cell structure CELL through the first opening OP1, and the upper surface of the second discharge structure DS2 may be exposed to the outside of the cell structure CELL through the second opening OP2.

By way of an example, an example to which a semiconductor device according to some example embodiments may be applied will be described below.

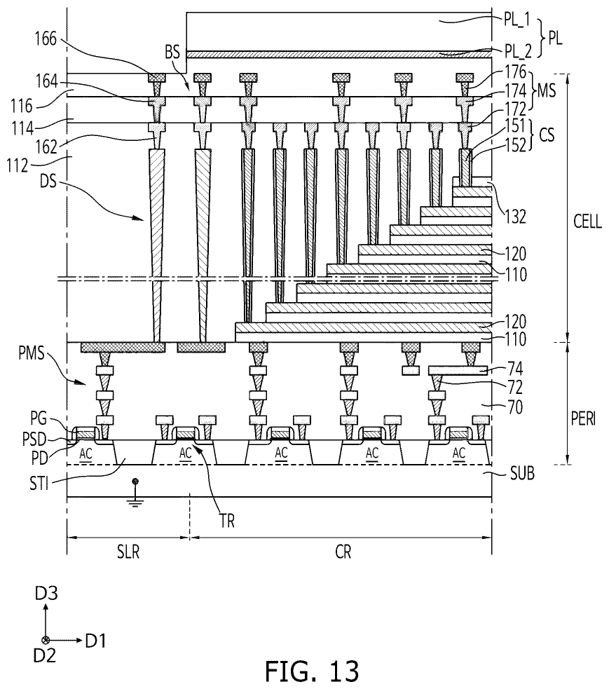

FIGS. 13 to 15 are cross-sectional views illustrating a semiconductor device including a discharge structure according to some example embodiments.

FIG. 13 illustrates a vertical memory device including the discharge structure DS. The semiconductor device may be a vertical memory device. However, this is only an example, and the semiconductor device may be various semiconductor devices such as DRAM and logic devices.

Referring to FIG. 13, the semiconductor device according to an example embodiment may include a substrate SUB, a peripheral circuit structure PERI, a cell structure CELL, a discharge structure DS, a block structure BS, a protective layer PL, etc.

The peripheral circuit structure PERI may be disposed on the substrate SUB. The peripheral circuit structure PERI may be disposed on the substrate SUB. A plurality of transistors TR forming a plurality of circuits may be provided on the substrate SUB. The peripheral circuit structure PERI may include a plurality of transistors TR.

The peripheral circuit structure PERI may include a device isolation film STI provided on the substrate SUB. The device isolation film STI may include a silicon oxide layer, a silicon nitride layer, or a combination thereof. An active region AC may be defined by the device isolation film STI.

Each of the plurality of transistors TR may include a gate and an active region. Each of the plurality of transistors TR may include a gate dielectric layer PD and a gate PG sequentially stacked on the substrate SUB, and a plurality of ion implantation regions PSD formed on both sides of the gate PG. The ion implantation region PSD may be formed in the active region AC. The plurality of ion implantation regions PSD may form a source region or a drain region of each transistor TR.

The peripheral circuit structure PERI may include a peripheral conductive line PMS. In some example embodiments, the peripheral circuit structure PERI may further include unit elements such as a resistor, a capacitor, etc.

The peripheral conductive line PMS may include a plurality of conductive plugs 72 and a plurality of conductive lines 74. However, example embodiments are not limited thereto. The plurality of transistors TR may be electrically connected to the cell structure CELL through the plurality of conductive plugs 72 and the plurality of conductive lines 74. The plurality of conductive plugs 72 and the plurality of conductive lines 74 may include tungsten, aluminum, copper, or a combination thereof, but not limited thereto.

The peripheral conductive line PMS may be in contact with the active region AC of the transistor TR. The peripheral conductive line PMS may be in contact with the ion implantation region PSD. The peripheral conductive line PMS may be in contact with the ion implantation region PSD and electrically connected to the substrate SUB.

The cell structure CELL may be disposed on the peripheral circuit structure PERI. In some example embodiments, the cell structure CELL may be disposed under the peripheral circuit structure PERI.

The cell structure CELL may include a stacked structure including a mold layer 120 and a word line 110 that are alternately stacked in the chip region CR in the third direction D3. The stacked structure may include a plurality of mold layers 120 covering upper and lower surfaces of each of a plurality of word lines 110. The plurality of mold layers 120 may include silicon oxide, silicon nitride, or SiON. The plurality of word lines 110 may include metal such as tungsten, nickel, cobalt, tantalum, etc., metal silicide such as tungsten silicide, nickel silicide, cobalt silicide, tantalum silicide, doped polysilicon, or a combination thereof.

Each of the plurality of contact structures CS may include a plurality of contact plugs 151 and contact insulating films 152. Each of the plurality of contact structures CS may extend in the third direction D3. Each of the plurality of contact structures CS may be in contact with a corresponding one of the plurality of word lines 110.

The wiring structure MS may be disposed on the contact structure CS. The wiring structure MS may include a first upper wiring layer 172, a second upper wiring layer 174, and the third upper wiring layer 176. Each of the first upper wiring layer 172, the second upper wiring layer 174, and the third upper wiring layer 176 may include tungsten, titanium, tantalum, copper, aluminum, titanium nitride, tantalum nitride, tungsten nitride, or a combination thereof.

Each of a plurality of channel structures (not shown) may be disposed to penetrate through the cell structure CELL in the cell region CR in the third direction D3. For example, each of a plurality of channel structures may include a gate dielectric layer, a channel region, a buried insulating film, and a drain region. The channel region may include doped polysilicon and/or undoped polysilicon. The channel region may have a cylindrical shape. The internal space of the channel region may be filled with the buried insulating film. The channel region may include a portion that is in contact with the common source line. The buried insulating film may include an insulating material. For example, the buried insulating film may include silicon oxide, silicon nitride, SiON, or a combination thereof.

In some example embodiments, the semiconductor device may include the discharge structure DS disposed in the scribe lane region SLR. The discharge structure DS may be formed through the cell structure CELL in the third direction D3. The upper surface of the discharge structure DS may be exposed to the outside of the cell structure CELL. The upper surface of the discharge structure DS may be positioned at the same vertical level as the upper surface of the wiring structure MS.

Electrons may flow into the discharge structure DS through the exposed upper surface. The electrons may flow along the discharge structure DS to the grounded substrate SUB. The discharge structure DS may be electrically connected to the active region AC of the transistor TR. The peripheral conductive line PMS of the peripheral circuit structure PERI may electrically connect the active region AC of the transistor TR to the discharge structure DS. As described above, the generated electrons may move to the active region AC and the substrate SUB of the transistor TR through the discharge structure DS and the peripheral conductive line PMS.

The block structure BS may extend in the third direction D3. The block structure BS may have the same structure as the discharge structure DS. The block structure BS may be positioned on a boundary between the chip region CR and the scribe lane region SLR. The block structure BS may overlap the boundary between the chip region CR and the scribe lane region SLR in the third direction D3.

The protective layer PL may be disposed on the cell structure CELL. The protective layer PL may cover at least a portion of the upper surface of the cell structure CELL. The protective layer PL may be disposed at a position that does not overlap the upper surface of the discharge structure DS in the third direction D3. The lower surface of the protective layer PL may be spaced apart from the upper surface of the wiring structure MS in the third direction D3.

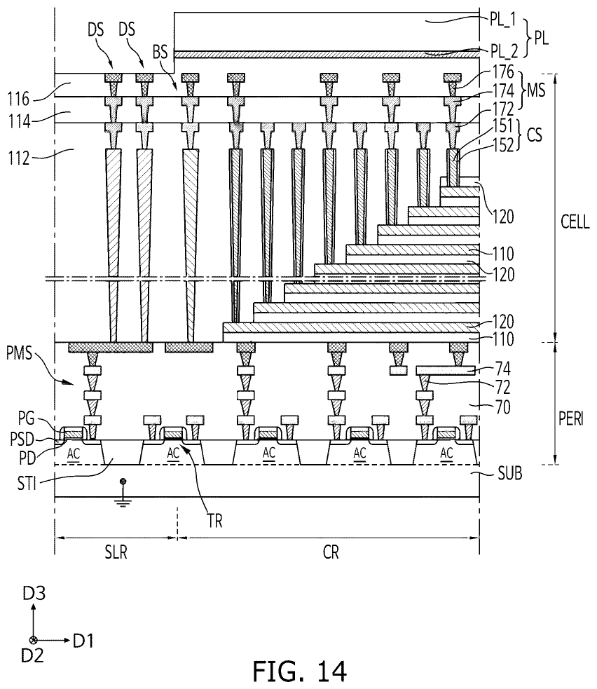

Referring to FIG. 14, a semiconductor device according to an example embodiment may include a plurality of discharge structures DS. The plurality of discharge structures DS may be spaced apart from each other in the first direction D1. In some example embodiments, the plurality of discharge structures DS may be disposed to be spaced apart from each other in the first direction D1 or the second direction D2. In some example embodiments, the plurality of discharge structures DS may be connected to each other.

The plurality of discharge structures DS may be electrically connected to the peripheral conductive line PMS, respectively. Electrons may move along each of the plurality of discharge structures DS. A lower end of each of the plurality of discharge structures DS may be in contact with the peripheral conductive line PMS. With the provision of the plurality of discharge structures DS, the movement path of electrons may increase. That is, the current density may decrease, and the resistance of the discharge structure DS may decrease.

Electrons that have moved along the plurality of discharge structures DS may move to the active region AC of the transistor TR through the peripheral conductive line PMS. That is, the generated electrons may move to the active region AC and the substrate SUB of the transistor TR through the discharge structure DS and the peripheral conductive line PMS.

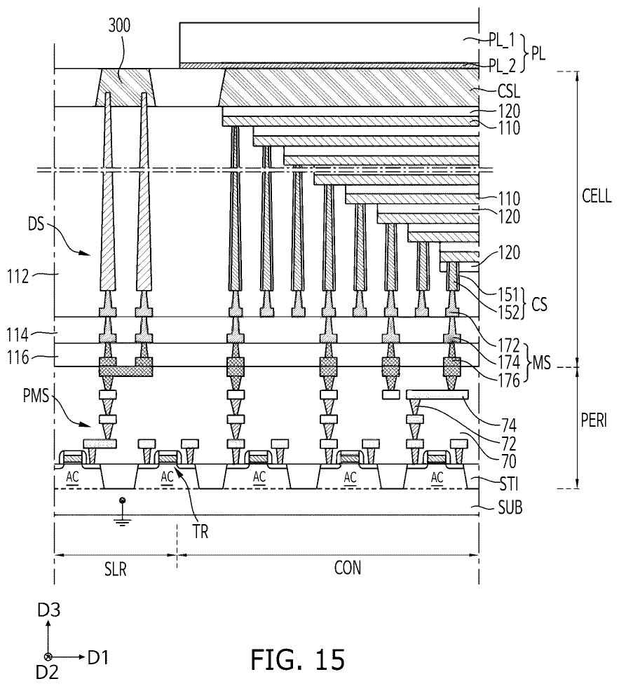

Referring to FIG. 15, a semiconductor device according to an example embodiment may have a chip to chip (C2C) structure. The C2C structure may be manufactured by forming the cell structure CELL on a first wafer, forming the peripheral circuit structure PERI on a second wafer different from the first wafer, and bonding the cell structure CELL and the peripheral circuit structure PERI. For example, the bonding method may include bonding the third upper wiring layer 176, which is the uppermost metal layer of the cell structure CELL, to the uppermost metal layer of the peripheral conductive line PMS of the peripheral circuit structure PERI. In some example embodiments, the third upper wiring layer 176 and the peripheral conductive line PMS may include copper (Cu) and bonded by a Cu—Cu bonding method. In some example embodiments, each of the third upper wiring layer 176 and the peripheral conductive line PMS may include aluminum (Al) or tungsten (W).

The cell structure CELL may include a common source line CSL. The common source line CSL may be spaced apart from the peripheral circuit structure CELL in the third direction D3 with the cell structure CELL interposed therebetween.

The cell structure CELL may include a discharge pad 300 disposed at the same level as the common source line CSL. The discharge pad 300 may include the same material as the common source line CSL. The common source line CSL and the discharge pad 300 may include metal, a conductive metal nitride, a semiconductor material, or a combination thereof. For example, the common source line CSL and the discharge pad 300 may include tungsten, titanium, tantalum, copper, aluminum, titanium nitride, tantalum nitride, tungsten nitride, or a combination thereof, but not limited thereto.

The discharge pad 300 may be disposed in the scribe lane region SLR. An upper surface of the discharge pad 300 may be exposed to the outside of the cell structure CELL. The discharge pad 300 may be exposed to the outside of the cell structure CELL through an opening formed by removing a portion of the protective layer PL. The discharge pad 300 may be disposed so as not to overlap the protective layer PL in the third direction D3. The discharge pad 300 may not be covered by the protective layer PL.

The upper surface of the discharge pad 300 may be open in the third direction D3. No separate wiring may be connected to the upper surface of the discharge pad 300. That is, the entirety or a portion of the upper surface of the discharge pad 300 may be exposed in the third direction D3. In other words, there may be no configuration in the opening that overlaps the protective layer PL in the first direction D1 or the second direction D2.

The discharge structure DS may be electrically connected to the discharge pad 300. The discharge structure DS may be in contact with the discharge pad 300. A portion of the discharge structure DS may be inserted into the discharge pad 300. Electrons flowing through the discharge pad 300 may move to the discharge structure DS.

Electrons formed around the protective layer PL may flow through the discharge pad 300. The electrons that have flown into the discharge pad 300 may move through the discharge structure DS. The electrons moving along the discharge structure DS may flow through the peripheral conductive line PMS to the active region AC of the transistor TR and the grounded substrate SUB.

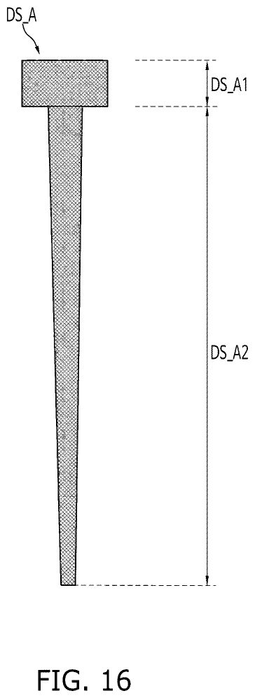

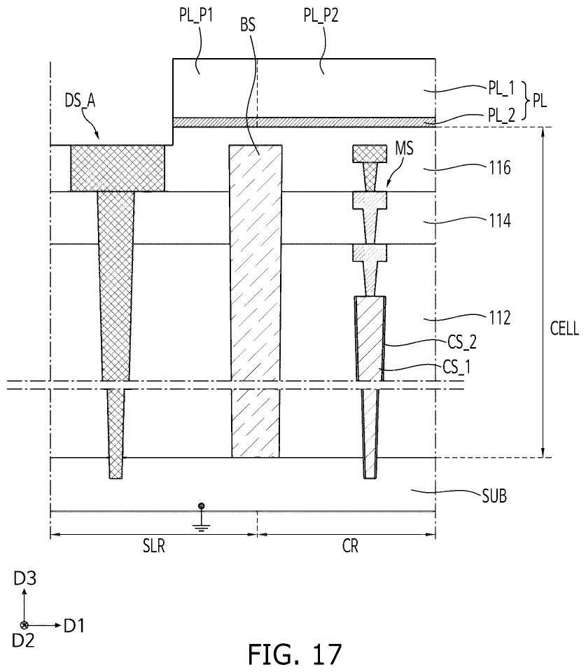

FIGS. 16 and 17 are diagrams provided to explain a discharge structure according to an example embodiment.

Referring to FIGS. 16 and 17, a discharge structure DS_A may include a metal material and may be integrally formed. The discharge structure DS_A may include tungsten, titanium, tantalum, copper, aluminum, titanium nitride, tantalum nitride, tungsten nitride, or a combination thereof. A first structure DS_A1 and a second structure DS_A2 may include the same material. That is, the first structure DS_A1 and the second structure DS_A2 may be integrally formed.

The discharge structure DS_A may include the first structure DS_A1 and the second structure DS_A2. The first structure DS_A1 may have a larger cross-sectional area than the second structure DS_A2 when viewed in a plan view (e.g., in the third direction D3).

The second structure DS_A2 may be connected to a lower surface of the first structure DS_A1. The second structure DS_A2 may extend in the third direction D3. For example, the second structure DS_A2 may be formed through the first interlayer insulating film 112 and the second interlayer insulating film 114. The first structure DS_A1 may be formed through the third interlayer insulating film 116. In some example embodiments, the first structure DS_A1 and the second structure DS_A2 may be formed by a single process.

Although the present disclosure has been described above by way of certain example embodiments and drawings, the present disclosure is not limited thereto, and it goes without saying that various changes and modifications can be made within the equivalent scope of the technical idea of the present disclosure and the claims to be described below by those of ordinary skill in the art.

What is claimed is:

1. A semiconductor device, comprising:
a substrate comprising a chip region and a scribe lane region, the chip region having a plurality of chips arranged in a first direction and in a second direction, the second direction intersecting the first direction, the scribe lane region surrounding the chip region;
a peripheral circuit structure on the substrate, the peripheral circuit structure comprising a transistor with a gate and an active region;
a cell structure on the peripheral circuit structure;
a protective layer on at least a portion of the cell structure; and
a discharge structure penetrating the cell structure in a third direction, the third direction intersecting each of the first direction and the second direction, the discharge structure electrically connected to the substrate,
wherein an upper surface of the discharge structure is exposed to an outside of the cell structure.

2. The semiconductor device according to claim 1, wherein the upper surface of the discharge structure is in the scribe lane region and is at a position not overlapping the protective layer in the third direction.

3. The semiconductor device according to claim 1, wherein the peripheral circuit structure further comprises a peripheral conductive line electrically connecting the active region of the transistor and the discharge structure.

4. The semiconductor device according to claim 1, wherein the discharge structure comprises:
a first structure exposed to an upper surface of the cell structure and comprising a metal material; and
a second structure electrically connected to the first structure and extending in the third direction.

5. The semiconductor device according to claim 1, wherein
the cell structure comprises a stacked structure, a contact structure, and a wiring structure, the stack structure on an upper surface of the peripheral circuit structure and comprising a mold layer and a word line layer alternately stacked in the chip region in the third direction, the contact structure on the stacked structure, and the wiring structure on the contact structure, and
the upper surface of the discharge structure and an upper surface of the wiring structure are positioned at a same vertical level.

6. The semiconductor device according to claim 5, wherein a lower surface of the protective layer is spaced apart from the upper surface of the wiring structure in the third direction.

7. The semiconductor device according to claim 1, wherein
the protective layer comprises a first portion in the scribe lane region and a second portion in the chip region, and
the semiconductor device further comprises a block structure overlapping a boundary between the first portion and the second portion in the third direction.

8. The semiconductor device according to claim 7, wherein the discharge structure and the block structure are electrically connected to each other.

9. The semiconductor device according to claim 7, wherein the upper surface of the discharge structure does not to overlap the first portion of the protective layer in the third direction in the scribe lane region.

10. The semiconductor device according to claim 7, further comprising:
an aperture extending through the second portion of the protective layer and a portion of the cell structure in the third direction,
wherein the discharge structure overlaps the aperture in the third direction and is exposed to the outside of the cell structure through the aperture.

11. The semiconductor device according to claim 10, wherein the block structure and the discharge structure are electrically connected to each other.

12. The semiconductor device according to claim 7, wherein an upper surface of the block structure is positioned at a same vertical level as the upper surface of the discharge structure.

13. The semiconductor device according to claim 1, wherein
the scribe lane region includes a corner region corresponding to a corresponding corner of the chip region, and an edge region corresponding to a corresponding edge of the chip region, and
the discharge structure is in at least one of the corner region or the edge region.

14. The semiconductor device according to claim 1, wherein
the cell structure comprises an interlayer insulating film, the interlayer insulating film being at a lower vertical level than the protective layer,
the interlayer insulating film comprises a first surface on a lower surface of the protective layer and a second surface uncovered by the protective layer, and
the second surface is at a lower vertical level than the first surface.

15. A semiconductor device, comprising:
a substrate comprising a chip region and a scribe lane region, the chip region having a plurality of chips arranged in a first direction and in a second direction, the second direction intersecting the first direction, the scribe lane region surrounding the chip region;
a peripheral circuit structure on the substrate, the peripheral circuit structure comprising a transistor with a gate and an active region;
a cell structure on the peripheral circuit structure;
a protective layer on at least a portion of the cell structure; and
a first discharge structure penetrating the cell structure in a third direction, the third direction intersecting each of the first direction and the second direction, the first discharge structure electrically connected to the substrate,
wherein an upper surface of the first discharge structure is exposed to an outside of the cell structure.

16. The semiconductor device according to claim 15, further comprising:
a block structure on a boundary between the chip region and the scribe lane region,
wherein the first discharge structure is spaced apart from the block structure in at least one of the first direction or the second direction and is in the scribe lane region.

17. The semiconductor device according to claim 15, further comprising:
a second discharge structure in the chip region, and
an aperture extending through at least a portion of the protective layer and a portion of the cell structure in the chip region in the third direction,
wherein an upper surface of the second discharge structure is exposed to the outside of the cell structure through the aperture, and the second discharge structure is electrically connected to the active region of the transistor.

18. The semiconductor device according to claim 15, wherein the protective layer comprises photosensitive polyimide.

19. The semiconductor device according to claim 15, wherein the first discharge structure comprises a metal material and is an integral structure.

20. A semiconductor device, comprising:
a substrate comprising a chip region and a scribe lane region, the chip region having a plurality of chips arranged in a first direction and in a second direction, the second direction intersecting the first direction, a scribe lane region surrounding the chip region;
a peripheral circuit structure on the substrate, the peripheral circuit structure comprising a transistor with a gate and an active region;
a cell structure on the peripheral circuit structure;
a protective layer on an upper surface of the cell structure and covering at least a portion of the cell structure; and
a discharge structure penetrating through the cell structure in a third direction, the third direction crossing each of the first direction and the second direction, an upper surface of the discharge structure not overlapping the protective layer in the third direction and exposed to an outside of the cell structure, and
the peripheral circuit structure further comprises a peripheral conductive line, the peripheral conductive line electrically connecting a lower surface of the discharge structure to the active region so that electrons flowing through the upper surface of the discharge structure move to the active region of the transistor.
